(19) United States
(12) Patent Application Publication
(10) Pub. No.: US 2019/0305516 A1
(43) Pub. Date: Oct. 3, 2019

(54) SELF-SEEDED FIBER OSCILLATOR

(71) Applicant: Cornell University, Ithaca, NY (US)

(72) Inventors: Frank Wise, Ithaca, NY (US); Zhanwei Liu, Sunnyvale, CA (US); Walter Fu, Ithaca, NY (US); Pavel Sidorenko, Ithaca, NY (US)

(21) Appl. No.: 16/367,005

(22) Filed: Mar. 27, 2019

Related U.S. Application Data
(60) Provisional application No. 62/648,876, filed on Mar. 27, 2018.

(51) Int. Cl. H01S 5/14; H01S 5/065; H01S 5/10; H01S 5/06; H01S 5/026; H01S 5/50

(52) U.S. Cl. CPC H01S 5/14; H01S 5/065; H01S 5/1064; H01S 5/50; H01S 5/0601; H01S 5/026; H01S 5/0609

(57) ABSTRACT

The technology described in this document can be used to implement an optical device for producing optical pulses that includes an optical oscillator including at least one optical arm including at least one piece of fiber and at least one optical filter, a starting arm coupled to the at least one optical arm to generate spikes of radiation for the optical oscillator to start pulsation, and an optical switch coupled between the optical oscillator and the starting arm to connect the starting arm to the at least one optical arm to start the optical oscillator using the spikes of radiation generated by the starting arm.

### PRIORITY CLAIMS AND RELATED PATENT APPLICATIONS

This patent document claims the priority and benefits of U.S. Provisional Application No. 62/648,876 entitled “SELF-STARTING FIBER OSCILLATOR FOR GENERATING FEMTOSECOND PULSES WITH MEGAWATT PEAK POWER” and filed on Mar. 27, 2018. The entirety of the above application is incorporated by reference as part of the disclosure of this patent document.

### STATEMENT OF GOVERNMENT SUPPORT

This invention was made with government support under Grant No. EB002019 awarded by the National Institutes of Health (NIH). This invention was also made with government support under Grant No. N00014-13-1-0649 awarded by the Office of Naval Research. The government has certain rights in the invention.

### TECHNICAL FIELD

This patent document discloses devices and techniques for generating optical pulses in fiber-based devices including fiber gain media.

### BACKGROUND

Mode-locked, rare earth-doped fiber lasers or oscillators can be used to generate short optical pulses for various applications including ultrafast applications.

### SUMMARY

This patent document discloses devices and techniques that use a filter bypass to start an optical oscillator that generates optical pulses for various applications including, e.g., nonlinear microscopy and x-ray generation. The disclosed devices and techniques can be used to produce short optical pulses having high peak power (e.g., megawatts) and short pulse durations (e.g., below 100 fs), being capable of starting without using external light sources and exhibiting desired environmental stability.

In one aspect, a method for generating optical pulses in an optical oscillator includes placing a main optical cavity structure including a plurality of cascaded optical regenerators, a plurality of spectral filters, and an output terminal, coupling a sub-cavity structure including a saturable absorber to the output terminal and one of the plurality of cascaded optical regenerators of the main optical cavity structure by bypassing one of the spectral filters, and adjusting the saturable absorber to generate pulses including powerful-enough spikes of radiation for the main cavity structure to start pulsation and allow pulsed lasing inside the oscillator.

In another aspect, a method for generating optical pulses in an optical oscillator including an optical cavity structure including a plurality of cascaded optical regenerators and a plurality of spectral filters includes bypassing one of the plurality of spectral filters to couple an output terminal of one of the cascaded optical regenerators to a saturable absorber to create an electric field fluctuation that is strong enough to start to generate seed pulses with Q-switched spectra, injecting the seed pulses to another cascaded optical regenerator to establish a pulsed state in the optical oscillator, and decoupling the saturable absorber from the output terminal of one of the cascaded optical regenerators and outputting the generated short pulses through the output terminal.

In another aspect, an optical device for producing optical pulses includes an optical oscillator including at least one optical arm including at least one piece of fiber and at least one optical filter; a starting arm coupled to the at least one optical arm to generate spikes of radiation for the optical oscillator to start pulsation; and an optical switch coupled between the optical oscillator and the starting arm to connect the starting arm to the at least one optical arm to start the optical oscillator using the spikes of radiation generated by the starting arm.

In another aspect, an optical device for producing optical pulses includes a plurality of cascaded optical regenerators including first and second optical regenerators, a plurality of spectral filters, each spectral filter being coupled between two consecutively arranged optical regenerators, a filter bypass path including a saturable absorber couplable to an output of the first optical regenerator by bypassing the spectral filter coupled between the first and second, and an optical switch configured to cause the filter bypass path to be engaged with or disengaged from the first and second optical regenerators. The saturable absorber is configured to generate pulses including powerful-enough spikes of radiation that can be injected as seed pulses into the second optical regenerator and start pulsation inside the plurality of cascaded optical regenerators.

### BRIEF DESCRIPTION OF THE DRAWINGS

FIG. 1 shows a schematic diagram of the self-seeded oscillator design implemented based on the disclosed technology.

FIG. 2. shows a schematic setup of a fiber oscillator implemented based on some embodiments of the disclosed technology.

FIG. 3A shows a sub-cavity and a first filter bypass. FIG. 3B shows a typical noisy pulse train, measured at the auxiliary output in the starting arm, with a main cavity blocked. FIG. 3C shows the spectrum averaged over many noisy pulses.

FIGS. 4A-4C show experimentally measured pulse generated by an oscillator depicted in FIG. 2 and externally dechirped using a grating compressor.

FIG. 5 shows schematic of the ring Mamyshev oscillator.

FIGS. 6A-6D show numerical simulation results for about 50 nJ output pulses.

FIGS. 7A and 7B show measurements of pulses from the ring Mamyshev oscillator.

FIG. 8A shows measured root-mean-square bandwidth after propagation through 2-m of standard single-mode fiber (SMF) compared to simulation. FIG. 8B shows radio frequency spectrum with a resolution bandwidth of 30 Hz and a span range of 20 kHz.

FIG. 9 shows an example of a self-seeded ring cavity optical oscillator implemented based on an embodiment of the disclosed technology.

FIG. 10 shows an example of a self-seeded linear cavity optical oscillator implemented based on another embodiment of the disclosed technology.

FIG. 11 shows an example method for generating optical pulses in an optical oscillator.

FIG. 12 shows an example method for generating optical pulses in an optical oscillator including an optical cavity structure including a plurality of cascaded optical regenerators and a plurality of spectral filters.

### DETAILED DESCRIPTION

The optical oscillation technology disclosed in this document provides a self-seeded optical oscillator implemented by adding a starting arm to an optical oscillator. In some implementations, the self-seeded optical oscillator may be implemented by adding a starting arm to a ring cavity oscillator. The self-seeded optical oscillator based on some embodiments of the disclosed technology may include a combination of cascaded optical regenerators and a bypass path including a saturable absorber. In an implementation, a self-seeded oscillator design may include two cascaded Mamyshev regenerators in a ring cavity that can be started by a simple operation of a mirror flip. In another implementation, the self-seeded optical oscillator may be implemented by adding a starting arm to a linear cavity oscillator such as a linear cavity Mamyshev oscillator.

The self-seeded optical oscillator can be implemented without any external light source and is environmentally stable because only polarization maintaining (PM) fibers are used in steady operation of the oscillator. In some implementations, the disclosed technology achieves a self-seeded environmentally stable oscillator with output that can be externally compressed to 35 femtoseconds and peak power that equals or exceeds three megawatts.

Cascaded Mamyshev regenerators can be environmentally stable. The first Mamyshev oscillators of the cascaded Mamyshev regenerators generate pulses as short as 150 fs. It is possible to start a Mamyshev oscillator by reflecting amplified spontaneous emission from an additional, coupled cavity back into the main oscillator cavity. In some implementations, optical oscillator devices can achieve self-seeded starting operation. For example, a device that generates 15-nJ and 150-fs pulses, for a peak power of about 100 kW, can achieves self-seeded starting operation through modulation of the power of the pump laser at about 10 kHz frequency.

An optical oscillation implemented based on some embodiments of the disclosed technology can be started by adding a coupled cavity to a Mamyshev oscillator. Motion of a single mirror in a way that first completes the starting cavity, and then completes the Mamyshev oscillator as described below, starts the oscillation reliably. The disclosed example configurations can start a Mamyshev oscillator with the parameters (primarily the spectral separation between the filters) required to support pulses with high peak power.

The self-seeded oscillators implemented based on the disclosed technology support an environmentally stable fiber-format that can be easily self-started, thus solving a major practical impediment to the widespread use of ultrashort pulse fiber sources in applications. High peak power and short duration of the generated pulses make the oscillator comparable to a solid state lasers like Ti:sapphire but still maintains all the advantages of fiber design.

In one implementation, for example, a method for generating optical pulses in an optical oscillator based on the disclosed technology may include a step of placing a main optical cavity structure including a plurality of cascaded optical regenerators, a plurality of spectral filters, and an output terminal, and a step of coupling a sub-cavity structure including a saturable absorber to the output terminal and one of the plurality of cascaded optical regenerators of the main optical cavity structure by bypassing one of the spectral filters, and a step of adjusting the saturable absorber to generate pulses including powerful-enough spikes of radiation for the main cavity structure to start pulsation and pulsed lasing inside the oscillator.

In another implementation, for example, a method for generating optical pulses in an optical oscillator including an optical cavity structure including a plurality of cascaded optical regenerators and a plurality of spectral filters may include a step of bypassing one of the plurality of spectral filters to couple an output terminal of one of the cascaded optical regenerators to a saturable absorber to create an electric field fluctuation that is strong enough to start to generate seed pulses with Q-switched spectra, a step of injecting the seed pulses to another cascaded optical regenerator to establish a pulsed state in the optical oscillator, and a step of decoupling the saturable absorber from the output terminal of one of the cascaded optical regenerators and outputting the generated short pulses through the output terminal.

In another implementation, for example, an optical device for producing optical pulses may be constructed based on the disclosed technology to include a plurality of cascaded optical regenerators including first and second optical regenerators, a plurality of spectral filters, each spectral filter being coupled between two consecutively arranged optical regenerators, a filter bypass path including a saturable absorber couplable to an output of the first optical regenerator by bypassing the spectral filter coupled between the first and second, and an optical switch configured to cause the filter bypass path to be engaged with or disengaged from the first and second optical regenerators. The saturable absorber is configured to generate pulses including powerful-enough spikes of radiation for the main cavity structure to inject seed pulses into the second optical regenerator and start pulsation inside the plurality of cascaded optical regenerators.

In an implementation of the disclosed technology, the self-seeded oscillator design is based on two concatenated Mamyshev regenerators inside a ring fiber cavity. A single stage of the Mamyshev's optical regenerator relies on the self-phase modulation (SPM) induced spectral broadening of the short optical pulse inside the fiber and followed by subsequent offset spectral filtering. When two spectral filters in the cascaded Mamyshev regenerator stages are offset one from another, it makes pulsed lasing threshold of the cavity above the threshold for mode-locking. Thus, the oscillator supports stable mode-locking and generation of clean, high-energy ultrashort pulses.

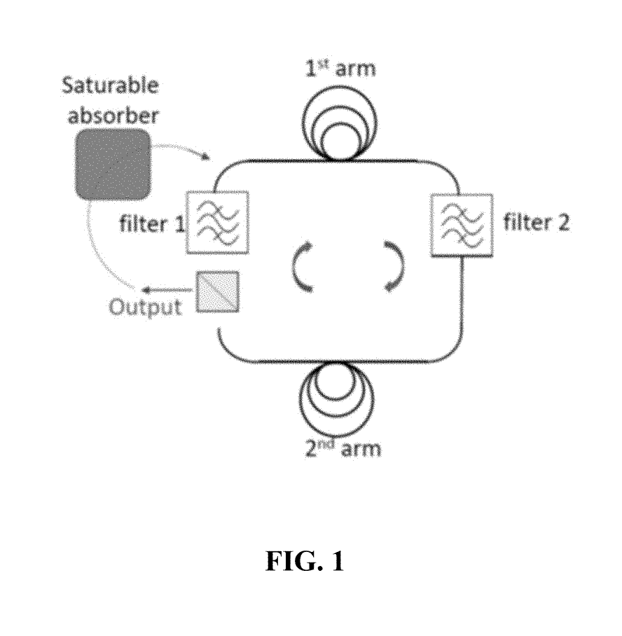

FIG. 1 shows a schematic diagram of the self-seeded oscillator design implemented based on the disclosed technology. To initiate pulsation in the cavity, the oscillator including a filter bypass and a saturable absorber creates an electric field fluctuation that is strong enough to sustain itself. To generate this fluctuation, an output of the oscillator bypasses the filter 1, passes through a saturable absorber, and is injected into the 1st arm.

The filter bypass of the self-seeded oscillator can be realized in different configurations depending on the filter structure. For example, if the filter is constructed with grating and collimator, the bypass can be realized by coupling light through zero diffraction order of the grating. For different filters, different bypasses can be realized. For example, for interference filters, the bypass can be realized by reflection from the interference filter. For fiber integrated filter, bypass can be realized by coupling light via rejection port.

The saturable absorber (SA) can be realized by different mechanisms including: SAs based on absorption saturation in semiconductors, carbon nanotubes, graphene, and artificial SAs such as nonlinear polarization evolution (NPE) and nonlinear loop mirrors.

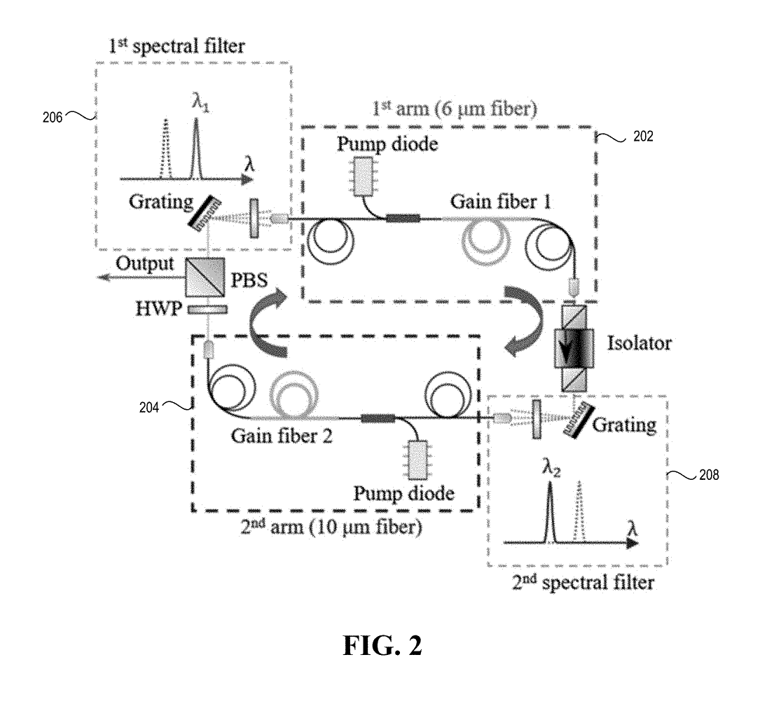

FIG. 2. shows a schematic setup of a fiber oscillator implemented based on some embodiments of the disclosed technology. A cavity is constructed by concatenating two Mamyshev regenerators (two “arms”). The fiber oscillator implemented based on some embodiments of the disclosed technology may include a first arm 202, a second arm 204, and first and second spectral filters 206 and 208. The first arm 202 acts mainly as a lower-energy feedback loop for the second arm. The second arm 204 acts as a power amplifier after which the main output is coupled out of the device. Two bandpass filters (206 and 208) with passbands centered at two different wavelengths that are offset from each other are provided to complete the regenerators and are placed between the arms.

A sub-cavity realized by bypassing the spectral filter in the second regeneration arm can start the pulsation of the main cavity. For example, the light from the main output is coupled to the gain fiber of the first arm through a zero order of the grating. This coupled cavity is completed by bringing up a single mirror on a flip mount and adjusted for the noisy Q-switched regime that generates powerful-enough spikes of radiation for the main cavity to start pulsation. Here, flip mirror may be used as the single mirror on a flip mount, but can be replaced with any kinematic mount or servo-controlled amount.

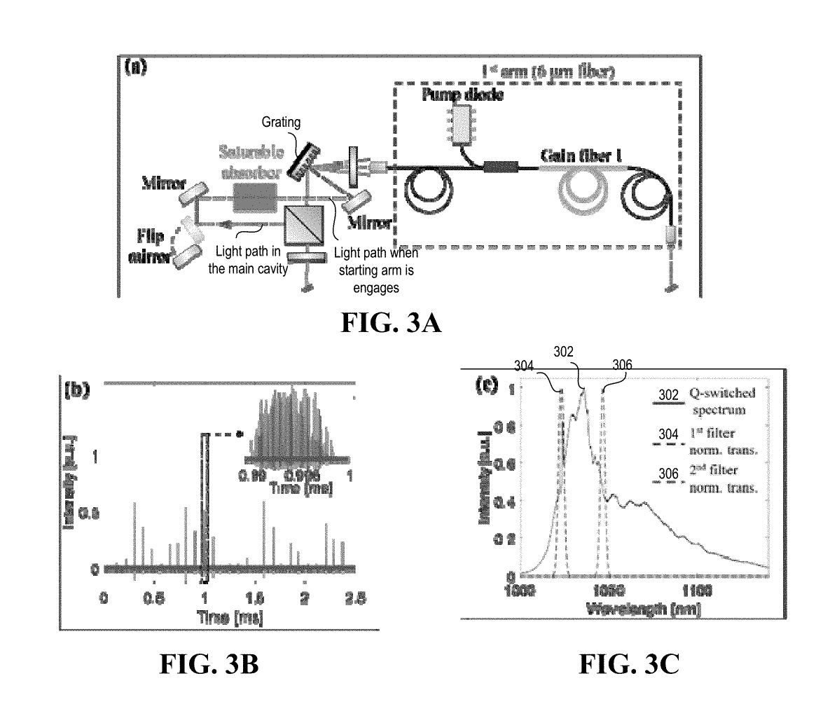

FIG. 3A shows sub-cavity and the first filter bypass. The dotted line indicates the light path in the main cavity and dashed line indicates the light path when starting arm is engaged (only one arm of the main cavity is shown). This bypassing allows pulsed lasing inside the oscillator. A saturable absorber (SA) in the starting arm enhances fluctuations that allow main cavity pulsation. In an implementation of the disclosed technology, a non-PM fiber segment and polarization elements form an effective SA through nonlinear polarization evolution (NPE). When the starting arm is engaged (e.g., using a flip mirror) and the SA is adjusted appropriately, noisy Q-switched pulses are generated in the cavity.

FIG. 3B shows a typical noisy Q-switched pulse train, measured at the auxiliary output in the starting arm, with the main cavity blocked. Inset shows expanded view of the pulse marked by black dashed box. FIG. 3C shows the spectrum averaged over 50 ms, i.e., over many noisy pulses. The curve 302 indicates the spectrum of pulse train. Dashed curves 304 and 306 correspond to the normalized transmissions of the first and second filters, respectively.

If the spectrum of the noisy Q-switched state spans the two filter passbands, simply engaging and disengaging the flip mirror starts the mode-locking most reliably. The bandwidth of a noisy pulse is inversely proportional to the shortest temporal fluctuation, which will have high peak power on average. Thus, the most-reliable self-seeding with the broadest Q-switched spectra can be obtained by properly setting the pump power in the first arm and wave plates controlling SA of the starting arm. The main cavity in this example implementation consists only of PM fiber, making it environmentally stable in steady-state operation (with the starting arm disengaged). While the use of NPE makes the starting arm sensitive to the environment, this does not affect the main cavity once the starting arm is disengaged. Replacing the NPE with an environmentally stable saturable absorber would serve comparably well, and allow even the starting arm to be PM. After initiation, mode-locking is self-sustaining and robust regardless of whether the starting arm is engaged.

Once the oscillator is mode-locked, the output coupling ratio (e.g., the half-wave plate before the polarizing beam splitter in FIG. 2) is adjusted to obtain the stable pulse train with highest pulse energy. The oscillator generates 4-ps chirped pulses with energy up to 190 nJ.

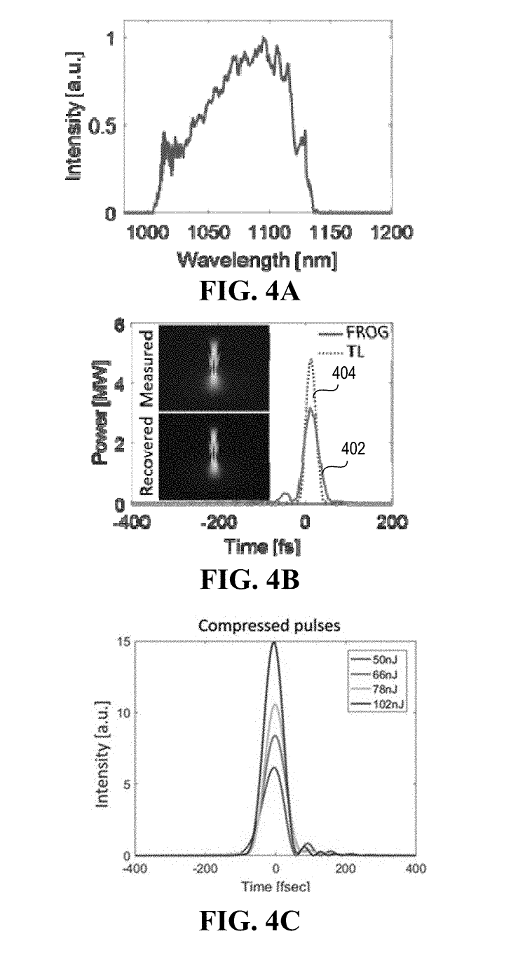

FIGS. 4A-4C show experimentally measured pulse generated by an oscillator depicted in FIG. 2 and externally dechirped using a grating compressor (1000 lines/mm). Oscillator may be started by starting arm (e.g., a mirror on a flip mount is used to complete the starting cavity), and compressed pulses may be characterized by second harmonic generation-frequency resolved optical gating (SFG-FROG). FIG. 4A shows measured spectrum of the pulse. FIG. 4B shows dechirped (402) and transform limited (TL) (404) pulses for 190 nJ pulse energy. Insets in FIG. 4B are measured and reconstructed SHG-FROG traces. Full width at half maximum of the compressed pulse is 35-fs (402 in FIG. 4B) and the 75% efficiency of the compressor is accounted for in the peak power plotted in FIG. 4B. FIG. 4C shows compressed pulses.

In another implementation of the disclosed technology, other types of SA can be used in starting arm including environmentally stable SA. Different types of filter bypass can be implemented, including, for example, a reflection from interference filter. The grating spectral filter may be replaced by another form of narrowband filter, such as an interference filter, a birefringent filter, a fiber Bragg device, or a photonic crystal structure. Multiple Mamyshev regenerator stages may be used in sequence to more precisely control the peak power and pulse shape. Different gain fibers may be used to generate pulses at different wavelengths. Fibers with different core diameters can be used, and the stable pulse energy will vary. In an example implementation, a combination of 6-μm and 10-μm cores may be used. In another example implementation, fibers with same core diameters can be used. For example, both arms include fiber with 6-μm core. In general, large core diameters will allow larger pulse energies.

Various implementations of the disclosed technology allow generation of short pulses with high peak powers. This constitutes a highly stable source that suit a wealth of applications ranging from nonlinear microscopy to x-ray generation. The short light pulse generator can start operation by injecting seed pulses through the seed input branch or by connecting the generator seed input branch with the generator output branch for a short time. In this way, the generator optical loop is spectrally opened for a short time period, e.g., the time period of said connecting is, approximately equal or shorter than time period within the light pulse travels around the generator optical loop, and, thus, it forms a laser resonator in which the seed pulses occurs from a spontaneous noise. The seed input and output branches of the generator can be optically connected by using, e.g., pulsed lasers, Q-switches, high-speed optical switches, both active and passive elements, such as accousto-optical modulator, Pockels cell, electro-optical modulator, mechanical switch, rotating prism or mirror, piezoelectric switch, semiconductor saturable absorber mirror (SESAM). Also, the ultra-short pulse generator can be started by overlapping spectral characteristics of the spectrally-selective optical elements for a short time period and, thereby, forming a laser resonator in which the seed pulses occurs from a spontaneous noise. The seed pulse parameters match only approximately with the generator output pulse parameters (e.g., duration, energy, spectrum width, spectral phase, temporal shape and so on) and can be different in several orders. After entering of the seed pulses in the generator optical loop, the generator pulses are formed after several roundtrips with the relevant characteristics, and at the output branch of the generator, the ultra-short light pulses with stable characteristics (e.g., energy, temporal, spectral) are generated. Not only one circulating pulse but also a certain number of pulses can be excited and generated inside the pulse generator optical loop. The ring circuit configuration of the pulse generator allows generation of contra-propagating pulses. The pulse generator is resistant to the Fresnel reflection and Fabry-Perot etalons that occur in the generator optical loop, and, for this reason, the generator optical loop can consist of different kind of optical fibers. Inside the optical loop, a hollow core photonic crystal fibers (PCF) can be spliced without fear of the Fresnel reflections that potentially may disturb the generator running. The pulse generator can be made of all-in-fiber design by splicing fibers with each other and with other fiber components (e.g., fiber hubs, WDM, fiber Bragg gratings, fiber polarizer, fiber mirrors, fiber pigtailed pump diodes). The generator can be made from the polarization-maintaining and non-maintaining optical fibers, single-mode and large-mode-area fibers. The generated pulses can be compressed down to the spectrum-limited pulse duration (e.g., femtoseconds) at the generator output by connecting the appropriate length of a hollow-core PCF fiber with the anomalous group velocity dispersion to the output branches of the generator (e.g. HC-1060 fiber, NKT Photonics).

Fiber lasers that generate ultrashort light pulses can offer practical advantages over solid-state lasers for some applications. However, the achievement of high peak power with environmentally stable designs remains a major challenge for fiber oscillators. Some embodiments of the disclosed technology can be used to implement an environmentally stable source based on cascaded Mamyshev regeneration that can reach peak power at least an order of magnitude higher than that of previous lasers with similar fiber mode area. By designing the oscillator to support parabolic pulse formation and exploiting the step-like saturable absorber characteristic of Mamyshev regeneration, unprecedented nonlinear phase shifts can be managed. Numerical simulations reveal key aspects of the pulse evolution and realistically suggest that (after external linear compression) peak powers approaching 10 MW are possible from an ordinary single-mode fiber. Experiments with a ring-cavity oscillator based on ytterbium-doped fibers are limited by available pump power, but they still yield 50-nJ and 40-fs pulses for about 1 MW peak power. The combination of environmental stability, established previously, with the performance described here should make the Mamyshev oscillator extremely attractive for applications.

Some embodiments of the disclosed technology can be used to provide an alternative to the solid-state mode-locked oscillator, with these purported benefits of the fiber platform: relatively low cost, simplicity, and robustness. Ultrafast lasers provide precise and intense fields that have enabled many important advances, such as biomedical imaging and laser micromachining. Fiber ultrafast instruments could be transformative in enabling both widespread scientific and industrial applications of ultrafast pulses. However, for this they must simultaneously reach sufficient performance and be amenable to both cost-effective manufacturing and use by non-experts. For a long time, the primary challenge to achieving high peak power was the management of nonlinearity in the waveguide medium. In the past decade, this challenge has been met with several developments. New pulse evolutions based in a normal dispersion fiber now provide a means of tolerating high nonlinearity. In laboratory prototypes that utilize nonlinear polarization evolution (NPE) as an effective saturable absorber, these sources rival solid-state oscillators. Their typical performance of about 20 nJ and sub-100 fs pulses from standard single-mode fiber (SMF) represent order of magnitude higher peak power than early soliton and stretched-pulse fiber oscillators. However, for widespread use and commercialization, NPE is undesirable, because it is highly sensitive to the random birefringence of the fiber, and consequently, mode-locking is easily disrupted by environmental perturbations. This has become the impediment to the proliferation of fiber lasers in applications that employ femtosecond oscillators.

Substantial effort has been devoted to solving this problem. Fiber lasers constructed with all polarization-maintaining (PM) fibers are robust against such environmental perturbations. To date, no work has been able to combine the high performance of NPE in standard SMFs with an all-PM design. Semiconductor saturable absorber mirrors (SESAMs) and nonlinear loop mirrors using PM fibers have been employed as alternative saturable absorbers. Material-based saturable absorbers, however, suffer from long-term reliability and poor power-handling capabilities. Nonlinear loop mirror (NOLM) and nonlinear amplifying loop mirror (NALM) based designs require precise control of the splitting ratio between loop directions, and their transmission cannot be easily and continuously tuned. Furthermore, although significant steps have been made, lasers based on SESAMs, NOLMs, and NALMs have still not generated more than 5-nJ and sub-100 fs pulses.

Devices based on reamplification and reshaping may be considered as an alternative for the generation of short pulses. This approach relies on self-phase-modulation (SPM) induced spectral broadening and offset spectral filtering, which leads to an effective self-amplitude modulation. Mamyshev proposes the use of the process for signal regeneration, and several studies focused mainly on pulse generation with telecommunication parameters. The pulse energies and durations (usually picojoules and picoseconds) may be limited by nonlinear phase accumulation in long fibers and narrow filter separation.

A Mamyshev oscillator may be used for high-energy femtosecond pulses. This environmentally stable oscillator may produce modest-energy (<3 nJ) pulses with 2-ps in duration. The measured spectral bandwidth may support about 150 fs transform-limited pulses. The oscillator may be started by reflecting light rejected by the filter back into the cavity. A Mamyshev oscillator may be started by modulating the pump laser at 20 kHz to induce Q—switching. This oscillator may feature an all-fiber construction and generated impressive 15-nJ pulses, which may be dechirped to 150-fs duration.

The Mamyshev oscillators have practical advantages over conventional mode-locked lasers. However, prior works do not address the nature of the intracavity pulse propagation beyond the self-amplitude modulation that arises from the offset filtering. As a result, important questions remain about fundamental aspects of their operation. Additionally, the peak power obtained with such devices still lags behind that of mode-locked lasers that employ NPE. If Mamyshev oscillators cannot reach high performance levels, the benefits they provide over alternative environmentally stable designs will be limited. Alternatively, if the performance limits of the Mamyshev oscillator meet or even exceed those of previous designs, the combination of performance and practical advantages may enable widespread applications. Clearly, there is ample motivation to understand pulse propagation and performance limits.

This patent document shows an example of the pulse propagation in a Mamyshev oscillator. The pulse propagation in the femtosecond optical oscillator implemented based on some embodiments of the disclosed technology shows good performance, yielding nearly an order of magnitude higher peak power. Numerical simulations show that an oscillator comprised of ordinary SMF, when seeded by a low-energy short pulse (<10 ps), can support mode-locked pulses with 190-nJ energy and <20 fs dechirped duration (Fourier transform-limited). These parameters correspond to about 8 MW peak power. The simulations reveal that this performance follows from the remarkable capacity of the oscillator to manage the nonlinear phase. In a suitably designed cavity, the pulse evolves to a parabolic shape before it enters the gain fiber, which enables control of the nonlinear phase accumulated in the gain segment. Theoretically, the pulse can accumulate a round-trip nonlinear phase shift of 140π and still be stable. In some implementations, about 50 nJ and about 40 fs pulses (after compression) at 17 MHz are generated, with the energy limited by the available pump power and/or damage to the PM fiber. Even so, the about 1 MW peak power is about 10 times higher than that produced by a mode-locked fiber laser constructed with ordinary SMF. The accumulated nonlinear phase shift is about 60π, which is about 5 times larger than the largest reported for stable pulses with well-controlled phase from a mode-locked laser. This may be attributed to the parabolic pulse propagation along with the step-like saturable absorber behavior of the Mamyshev process, which will be elaborated on below. These results represent a significant step toward a high-energy, short-pulse fiber source that can be environmentally stable. The outlook for self-seeded Mamyshev oscillators, along with extensions to other wavelengths, will be discussed below.

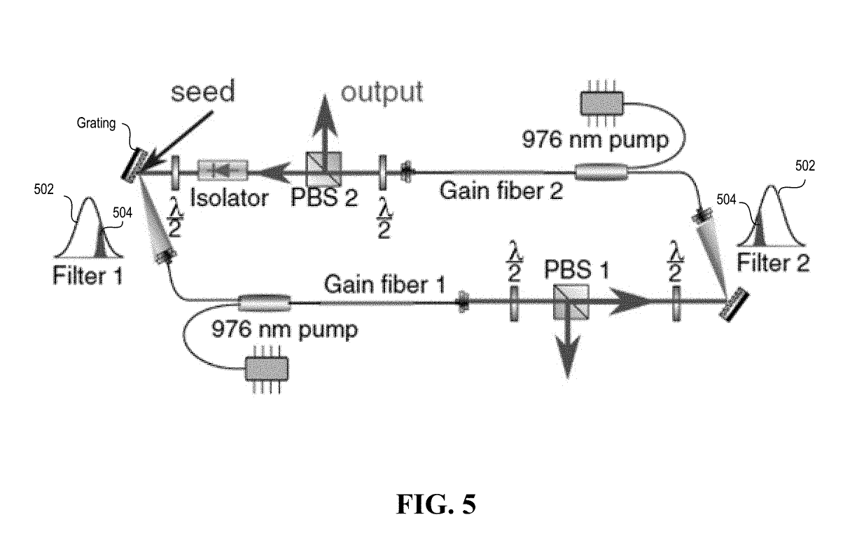

FIG. 5 shows schematic of the ring Mamyshev oscillator. The curve 502 shows the gain spectrum and the curve 504 indicates the passband of the filter. PBS indicates polarizing beam splitter. The laser operates in the all-normal dispersion regime (as do all prior Mamyshev oscillators). A ring oscillator allows more design freedom to control the propagation, compared to a linear oscillator. The ytterbium-doped fiber provides the gain, and all fibers are PM. The use of Gaussian spectral filters is important for maximizing the pulse quality and peak performance (see Supplement 1, section 3). To accomplish this, we use the overlap of the beam diffracted from a grating with the spatial mode of the fiber. These filters inherit the Gaussian shape from the fundamental mode shape of the SMF, and they were tuned to longer (˜1040 nm) and shorter (˜1030 nm) wavelengths than the 1035 nm peak of the gain spectrum. An isolator ensures unidirectional operation. Polarizing beam splitters (PBS) are used as the output couplers. The steady-state operation cycle consists of amplification (gain fiber 1), spectral broadening (gain fiber 1 and the following passive SMF), pulse energy adjustment (PBS 1), filtering (filter 2), amplification (gain fiber 2), spectral broadening (gain fiber 2 and the following passive SMF), output (PBS 2), and spectral filtering (filter 1). Half-wave plates are used to adjust the polarization state of light going into the PM fiber and to optimize the output coupling ratio. To ignite pulsation in the cavity, seed pulses are directed into the fiber via a grating.

In some implementations, a standard split-step method can be used based on accurate fiber parameters. The simulation includes the Kerr nonlinearity, stimulated Raman scattering, and second and third-order dispersion. The oscillator is seeded with different initial pulses (picosecond or femtosecond duration), but for given cavity parameters, the simulations always converge to the same solution. The cavity may generate up to 190-nJ pulses, which can be dechirped to below 20 fs. The pulse energy is limited by deviations of the pulse from a parabolic shape, which causes wave breaking, and by stimulated Raman scattering.

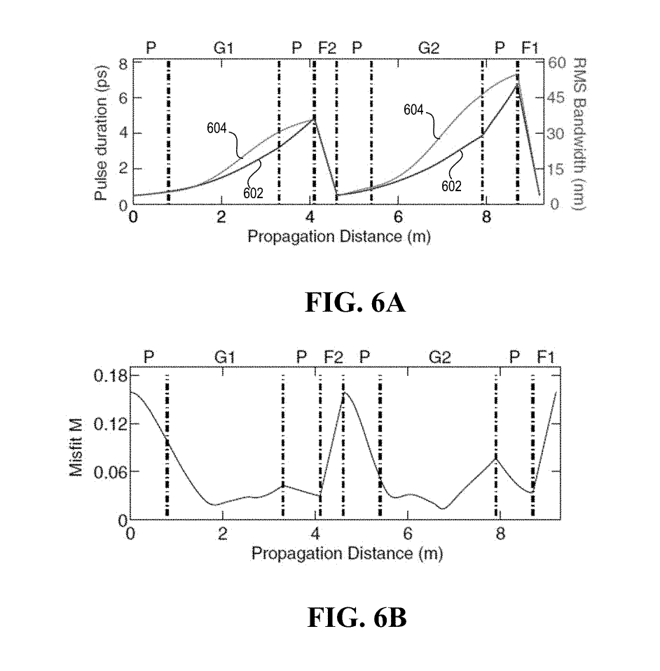

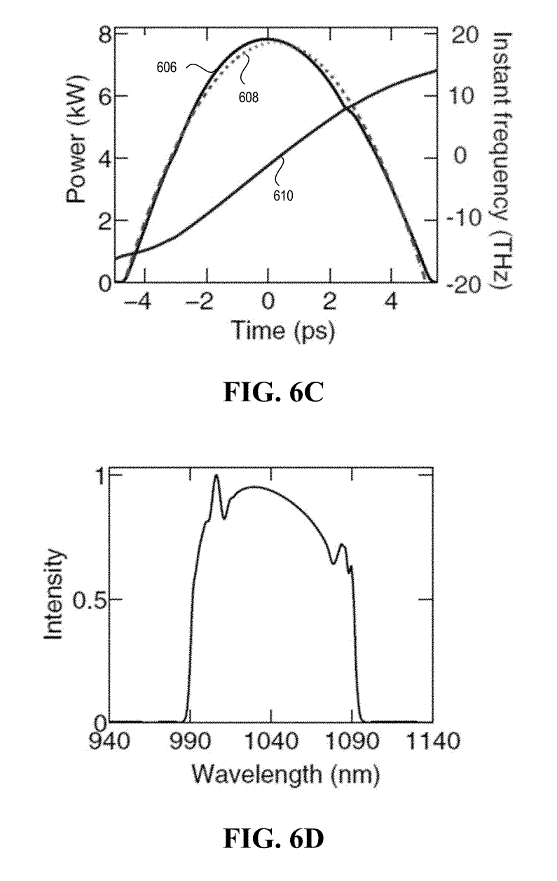

FIGS. 6A-6D show numerical simulation results for about 50 nJ output pulses. FIG. 6A shows evolution of pulse duration (602) and RMS bandwidth (604) where P indicate passive fiber, G indicates gain fiber, and F indicates filter. FIG. 6B shows evolution of misfit parameter M defined by M²=f (1−I fit)dt/f I²dt, which indicates the difference between the pulse shape (I) and the best-fit parabolic profile I_{fit}. FIG. 6C shows temporal profile (606) with fitted parabolic curve (608) and instantaneous frequency across the chirped pulse (610). FIG. 6D shows simulated spectrum.

The pulse duration and bandwidth grow monotonically in the passive (80 cm), gain (2.5 m) and second passive fiber (80 cm) segments in both arms. The spectral filters (F1 and F2) shape the pulse to a narrow-band and short-duration pulse that seeds the propagation in the subsequent arm (FIG. 6A). Over the course of its evolution, spectral breathing by a factor of 16 is observed. The pulse evolves quickly to a parabolic shape in the passive fiber (FIG. 6B). This parabolic pulse is subsequently amplified in the gain fiber. The parabolic shape is maintained through this gain fiber and into the following passive fiber. This is in contrast to regenerative similariton lasers, where the self-similar evolution is localized to the gain fiber. The output in the time domain is a nearly linearly chirped parabola (FIG. 6C) with 110-nm bandwidth (FIG. 6D), which corresponds to a 30 fs transform-limited pulse.

A Yb-doped, PM double-clad fiber with 6-μm core may be employed in the gain segments. The 2.5-m-long gain segments support the parabolic evolution and absorb most of the pump light. For example, all the passive fibers may be standard passive fibers (e.g., PM-980). The repetition rate of the oscillator is about 17 MHz. The separation of the two filters may be adjusted to eliminate continuous-wave (CW) operation, while allowing for the highest output pulse energy. With the seed pulses launched into the cavity, the optimal mode-locking conditions may be found by adjusting the output coupling in each arm with the waveplates. The seed pulses can be quite weak, and their duration is not important. For example, reliable starting may be obtained with 80-pJ and 10-ps pulses or with <10 pJ and 3-ps chirped pulses with 20-nm bandwidth. The bandwidth of the seed pulses is a significant factor, because it determines whether a seed can circulate and be amplified in the first round-trip; if the bandwidth is not wide enough, larger seed energy or higher gain is needed to provide enough spectral broadening. Once pulsation is initiated, as indicated by a broad output spectrum, the seed pulse can be blocked and pulses will continue to circulate in the cavity. While the oscillator is running, physical perturbations such as twisting or shaking the fiber do not alter the operating state of the laser. Once the optimal conditions are found, oscillation can be extinguished by blocking the cavity or turning off the pump and then restarted to the same state by launching seed pulses without any additional adjustment. Moreover, an isolated seed pulse is not necessary, as the pulsed operation is stable in the presence of continuous seeding. As another example, different continuously running pulsed lasers may be used as seed sources, operating at 1 MHz and 40 MHz.

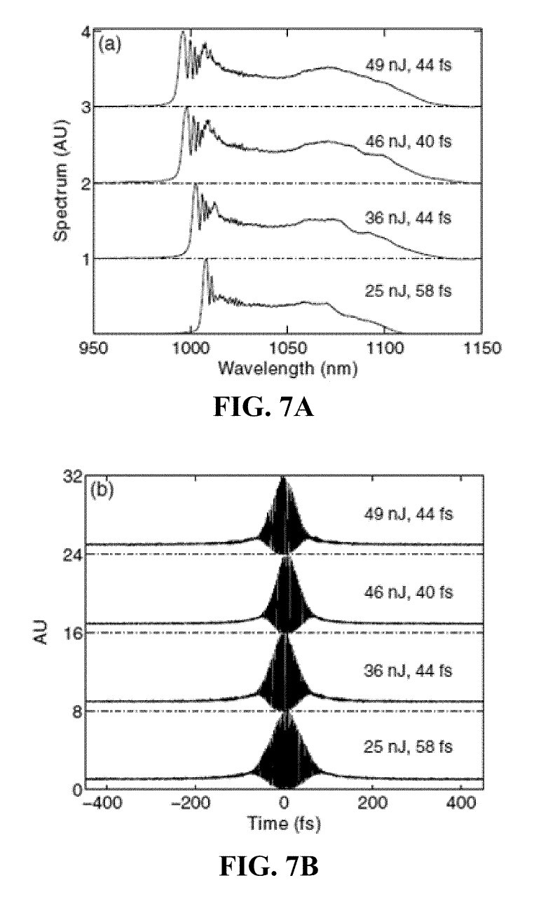

FIGS. 7A and 7B show measurements of pulses from the ring Mamyshev oscillator. Specifically, FIG. 7A shows measured output spectra, and FIG. 7B shows autocorrelations for the indicated output energies. The oscillator generates 6-ps chirped pulses. The output spectra and autocorrelation traces of the dechirped pulses for a range of pulse energies are shown in FIG. 3. Here the output is taken from the output coupler directly before the isolator, and the energy is modified by changing the pump power. As the energy in-creases, the spectrum broadens due to stronger SPM (FIG. 7A), and the dechirped duration decreases. Using only a grating compressor (300 lines/mm), the dechirped pulses appear relatively clean, without pedestals or structure (FIG. 7B). For the energy range shown, the dechirped pulse duration is within 1.5 times the transform limit. This deviation can be accounted for by the third-order dispersion in the grating compressor. The 50-nJ pulses accumulate a nonlinear phase of 60π. This shows that the huge nonlinear phase accumulation in the Mamyshev oscillator is well-controlled: it is converted into a nearly linear chirp. Eventually, the higher-order phase, which cannot be compensated by the grating pair, becomes significant, and the minimum dechirped duration grows, despite increasing band-width (50-nJ trace). The 50 nJ pulses are limited by the maximum available pump power. In this way, multi-pulsing, which commonly limits the pulse energy in mode-locked lasers, may be avoided.

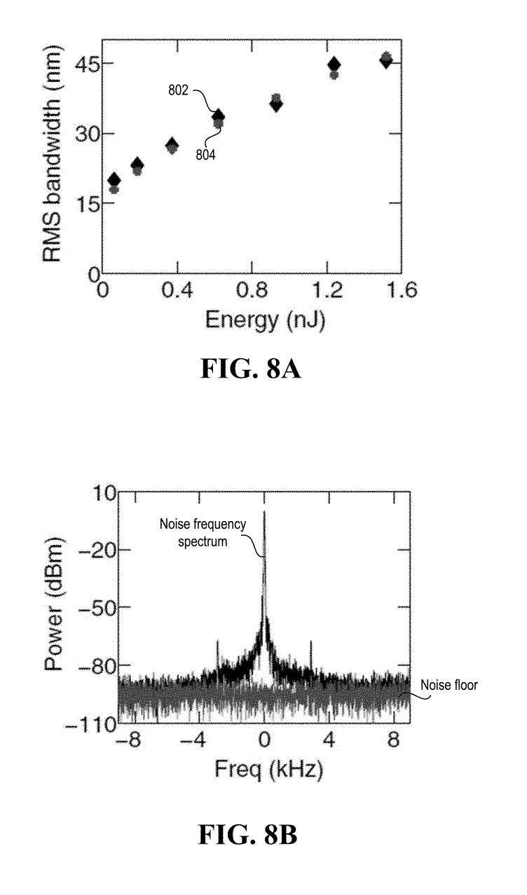

FIG. 8A shows measured root-mean-square bandwidth after propagation through 2-m of SMF (802) compared to simulation (804). FIG. 8B shows radio frequency spectrum with a resolution bandwidth of 30 Hz and a span range of 20 kHz.

Nonlinear phase is well-controlled: it is converted into a nearly linear frequency sweep. Eventually, the higher-order phase, which cannot be compensated by the grating pair, becomes significant, and the minimum dechirped duration grows, despite increasing bandwidth (50-nJ trace). The 50 nJ pulses are limited by the maximum available pump power; we do not observe multi-pulsing, which commonly limits the pulse energy in mode-locked lasers.

The pulse peak power is verified by launching the dechirped pulse into 2-m of SMF with a 6 μm core diameter (HI1060) and measuring the SPM-induced spectral broadening. The measurements are compared with the results of numerical simulations in FIG. 8A. In simulation, we launch a Gaussian pulse with the same energy and transform-limited duration and, with the residual third-order dispersion from the grating compressor, into a fiber with the parameters of 2-m of HI1060. The calculation accounts for fiber dispersion up to the third order, SPM, and intrapulse Raman scattering. The simulation reproduces the root-mean-square bandwidth observed for the experimental pulses accurately, which indicates the high quality of the output pulses.

The stability of the output pulse train may be investigated using an RF spectrum analyzer. The resolution and dynamic range of the spectra are instrument-limited but still confirm the stable mode-locking and absence of sidebands and harmonic frequencies to at least 80 dB below the fundamental frequency (FIG. 8B). This is similar to the performance of mode-locked fiber oscillators.

For the conditions described above, the oscillator does not start from noise. Self-pulsation originating from amplified spontaneous emission (ASE) has been predicted and demonstrated in long cavities (˜km) with highly nonlinear fibers (HNLF). Starting is favorable in these cavities owing to the narrow filter separation, along with the possibility for sufficient nonlinear phase accumulation by even low-power fluctuations in the long HNLF. The dissipative Faraday instability (DFI) can account for self-seeded starting in this case, since the small separation between the filters overlaps with the DFI gain spectrum. For broadband, high-energy pulses, the optimal filter separation is much broader than the DFI gain spectrum. In this regime, self-seeded starting may be proposed by the use of controlled feedback of ASE in the linear cavity.

The performance of mode-locked lasers is fundamentally limited by nonlinear effects. Solitons and dispersion-managed solitons are stable for, at most, a round-trip peak nonlinear phase shift of 71 Experiments showed that passive similariton, dissipative soliton, and amplifier similariton can support <100 fs and >10 nJ pulses, which corresponds to an 10π nonlinear phase shift. Simulations of these evolutions, assuming ideal saturable absorbers, indicate that higher performance can be achieved with higher pump power. These high-energy pulses, that is, larger nonlinear phase shift, require a very high modulation-depth saturable absorber to suppress the CW background. While NPE can be close to an ideal absorber, there is still a significant gap between simulations and experiments, and currently 10π represents an approximate limit for experiments. This value is consistent with the numerical prediction for dissipative soliton oscillators. Table 1 summarizes the performance of representative Yb-doped mode-locked fiber lasers. Actual pulse energies are scaled to the values that would be obtained with the same core size (6 μm).

TABLE 1

| | Nonlinear | Typical | Best |
|---|---|---|---|
| Pulse Evolution | Phase | Performance | Performance |
| Soliton | ~0 | 0.1 nJ, 300 fs | 0.5 nJ, 100 fs |
| Stretched pulses | 0-π | 1 nJ, 100 fs | up to 3 nJ, |
| | | | down to 50 fs |
| Passive similariton | 2π-10π | 6 nJ, 150 fs | 15 nJ, 100 fs |
| Dissipative soliton | 2π-10π | 6 nJ, 150 fs | up to 20 nJ, |
| | | | down to 70 fs |
| Amplifier | 4π-10π | 3 nJ, 70 fs | up to 8 nJ, 40 fs |
| similariton | | | |
| Ti:sapphire | 0-π | 30 nJ, | 200 nJ, 30 fs |
| | | 50-100 fs | |
| Mamyshev | >60π | | experiment: |
| oscillator | (in simulation: | | 50 nJ, 40 fs |
| | >140π) | | (in simulation: |
| | | | >190 nJ, <20 fs) |

The Mamyshev oscillator overcomes these limitations. If the nonlinearity is correctly managed, high-energy, wave-breaking-free pulses with good phase profile can be generated, apparently even well beyond the gain bandwidth limit. This performance follows from the step-like saturable absorber realized by the combination of two filters and the fiber. The cascaded frequency-broadening and offset filtering creates an effective transmission function that is step-like, with zero transmittance at low power and an abrupt transition to a constant value at high power. This step-like saturable absorber means that the mode-locking pumping rate is below the CW lasing threshold. Therefore, the Mamyshev oscillator only supports mode-locked operation. This eliminates the nonlinearity limit from the saturable absorber and allows for much higher energy.

Examples of methods of starting cavities may include pump modulation and controlled feedback of ASE. Using a coupled cavity to start the Mamyshev oscillator has the practical benefit of being completely passive. Starting the oscillator from a pulse systematically produces higher performance than starting from noise. In contrast, the self-seeded linear Mamyshev oscillator show that pulse-seeded and starting performance are similar. Meanwhile, standard numerical techniques for modeling ultrashort-pulse fiber lasers neglect gain relaxation dynamics and use a restricted temporal window. These fail to account for nanosecond laser spiking or other effects that may play an important role in starting and, ultimately, the steady-state performance. In the Mamyshev oscillator, CW lasing is completely suppressed: the CW lasing threshold is much higher than the pulse threshold. Consequently, if achieved, starting should be more deterministic, and the maximal nonlinear phase shift can be much higher than in a cavity where CW lasing needs to be constantly suppressed.

Some embodiments of the disclosed technology can be extended in several directions. In some implementations, Mamyshev oscillators will reach the microjoule level. Simulations also indicate that by changing the fiber length, the oscillator repetition rate can be tuned from hundreds of MHz to about 1 MHz without sacrificing the performance (at lower repetition rates, additional dispersion compensation inside of the cavity is required). This will allow it to be a useful tool for both scientific and industrial applications. In addition, linearly chirped parabolic output pulses are attractive for applications such as highly coherent continuum sources and optical signal processing, etc. High performance Mamyshev oscillators at other wavelengths can be used to implement various embodiments of the disclosed technology.

Some embodiments of the disclosed technology may be used for optimization of the Mamyshev oscillator for signal regeneration. A crucial difference between the Mamyshev oscillator and a conventional mode-locked laser is that, in the Mamyshev oscillator, the pulsed state is bistable with ASE. This kind of bistability is also a key characteristic of systems supporting cavity solitons (where usually the pulsed state is bistable with the CW field). Hence, the Mamyshev oscillator should be compared and contrasted not only with mode-locked lasers but also with systems that support cavity solitons, such as coherently driven cavities, which have lately been explored extensively for producing mode-locked frequency combs. The pulse evolution has following features. First, the Mamyshev oscillator can produce a stable pulse train, even with extremely high round-trip nonlinear phase shift and spectro-temporal breathing. This suggests that in a suitably designed device, an octave-spanning frequency comb could be generated directly, possibly exceeding the bandwidth, and certainly the power, of microresonator combs. Second, as in fiber lasers, the round-trip gain and loss are much higher than in coherently driven cavities. This may allow more straightforward control over circulating pulses, at the point of minimum pulse energy by, for example, an intracavity electro-optic modulator or coupling to an external source of optical bits.

The Mamyshev oscillator allows a surprising and significant leap in the ongoing central challenge of high-power ultrafast fiber lasers: the management of nonlinearity. This is due to the formation and amplification of parabolic pulses and the step-like artificial saturable absorber formed by the Mamyshev regeneration mechanism. By making the CW lasing threshold above the threshold for mode-locking, the Mamyshev oscillator supports stable mode-locking with huge nonlinear phase shifts. To harness this nonlinearity for the generation of clean, high-energy ultrashort pulses, the oscillator implemented based on some embodiments of the disclosed technology may support parabolic pulse formation. Combined, these factors translate to unprecedented performance, the oscillator implemented based on some embodiments of the disclosed technology yields an order of magnitude higher peak power than any previous fiber oscillator with the same core size. The Mamyshev oscillator supports an environmentally stable, fiber-format design that can be self-seeded, thus solving a major practical impediment to the widespread use of ultrashort-pulse fiber sources in applications.

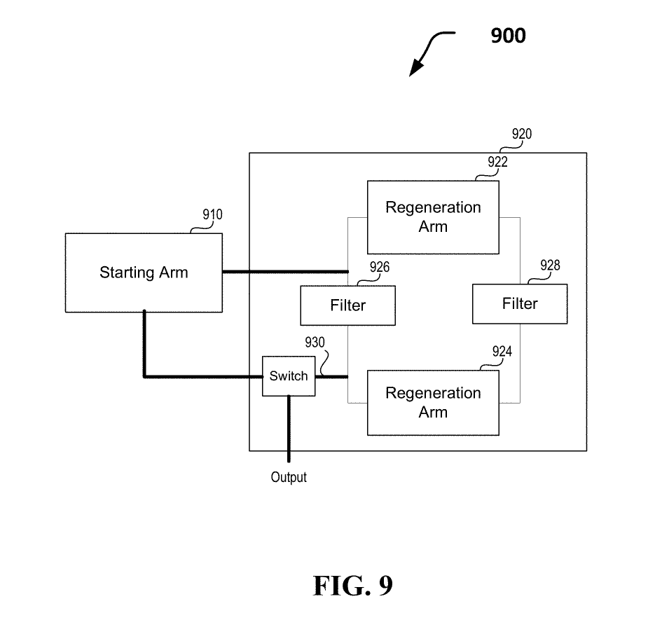

FIG. 9 shows an example of a self-seeded ring cavity optical oscillator 900 implemented based on an embodiment of the disclosed technology. A self-seeded ring cavity optical oscillator may be implemented by adding a starting arm 910 to a ring cavity oscillator 920. In an implementation, a self-seeded oscillator design may include two cascaded Mamyshev regenerators 922 and 924 in a ring cavity 920 that can be started by a starting arm 910 without using any external light source. For example, a starting arm 910 may be realized by bypassing a spectral filter 926 in the second regeneration arm 924. Light from a main output 930 is coupled to a gain fiber of a regeneration arm 922 to generate spikes of radiation for the ring cavity oscillator 920 to start pulsation.

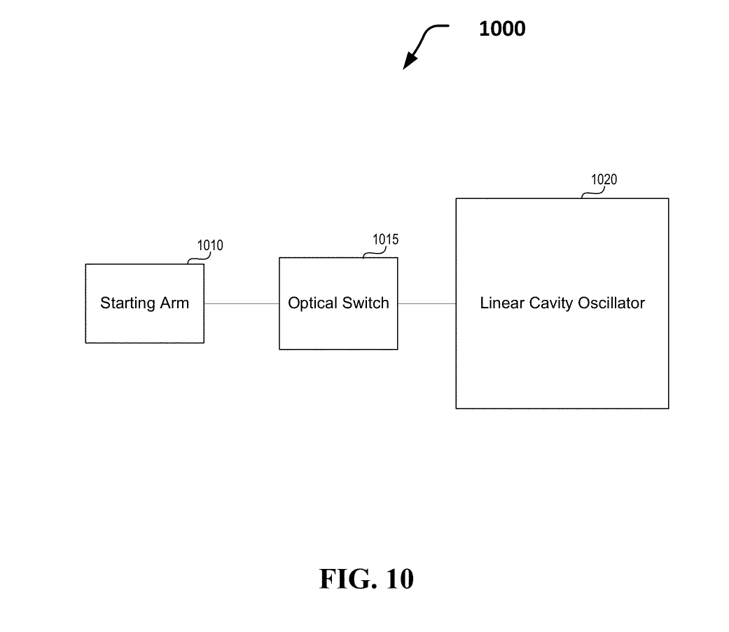

FIG. 10 shows an example of a self-seeded linear cavity optical oscillator 1000 implemented based on another embodiment of the disclosed technology. The self-seeded linear cavity optical oscillator 1000 may include a starting arm 1010, an optical switch 1015, and a linear cavity oscillator 1020. The self-seeded linear cavity optical oscillator 1000 may be implemented by adding a starting arm 1010 to a linear-cavity oscillator 1020 such as a linear cavity Mamyshev oscillator. In some implementations, the linear cavity Mamyshev oscillator may include one piece of fiber, two filters and two mirrors, one on each end. Unlike the ring cavity where light goes through two pieces of fiber, light in a linear cavity goes back and forth through one piece of fiber Like the starting arm in the ring cavity, however, light coupled to the fiber in the linear cavity may generate spikes of radiation for the linear cavity oscillator 1020 to start pulsation.

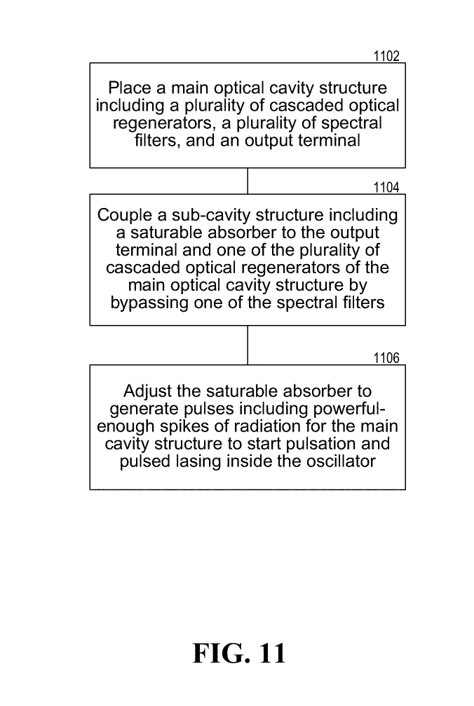

FIG. 11 shows an example method for generating optical pulses in an optical oscillator. The method includes, at step 1102, placing a main optical cavity structure including a plurality of cascaded optical regenerators, a plurality of spectral filters, and an output terminal, at step 1104, coupling a sub-cavity structure including a saturable absorber to the output terminal and one of the plurality of cascaded optical regenerators of the main optical cavity structure by bypassing one of the spectral filters, and at step 1106, adjusting the saturable absorber to generate pulses including powerful-enough spikes of radiation for the main cavity structure to start pulsation and pulsed lasing inside the oscillator.

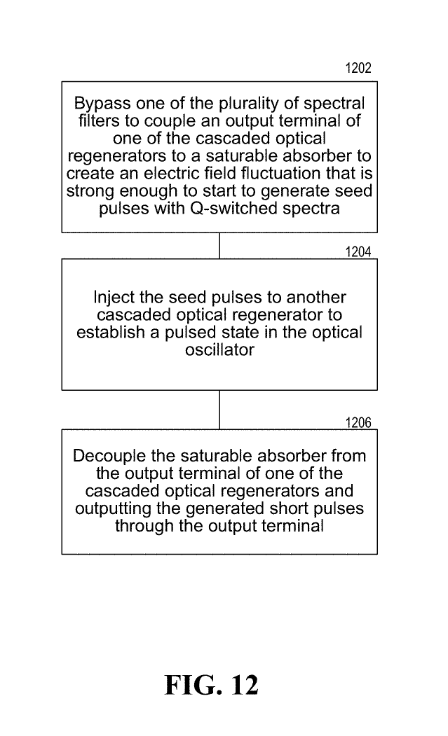

FIG. 12 shows an example method for generating optical pulses in an optical oscillator including an optical cavity structure including a plurality of cascaded optical regenerators and a plurality of spectral filters. The method includes, at step 1202, bypassing one of the plurality of spectral filters to couple an output terminal of one of the cascaded optical regenerators to a saturable absorber to create an electric field fluctuation that is strong enough to start to generate a seed laser with Q-switched spectra, at step 1204, injecting seed pulses to another cascaded optical regenerator to establish a pulsed state in the optical oscillator, and at step 1206, decoupling the saturable absorber from the output terminal of one of the cascaded optical regenerators and outputting the generated short pulses through the output terminal.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments. Only a few implementations and examples are described and other implementations, enhancements and variations can be made based on what is described and illustrated in this patent document.

What is claimed is:

1. A method for generating optical pulses in an optical oscillator, comprising:
placing a main optical cavity structure including a plurality of cascaded optical regenerators, a plurality of spectral filters, and an output terminal;
coupling a sub-cavity structure including a saturable absorber to the output terminal and one of the plurality of cascaded optical regenerators of the main optical cavity structure by bypassing one of the spectral filters; and
adjusting the saturable absorber to generate pulses including powerful-enough spikes of radiation for the main cavity structure to start pulsation and pulsed lasing inside the oscillator.

2. The method as in claim 1, further comprising adjusting an output coupling ratio at the output terminal to obtain a stable pulse train with a high pulse energy.

3. The method as in claim 2, further comprising decoupling the sub-cavity structure from the main optical cavity structure after the optical oscillator is mode-locked.

4. The method as in claim 1, wherein the optical regenerator includes a Mamyshev regenerator.

5. A method for generating optical pulses in an optical oscillator including an optical cavity structure including a plurality of cascaded optical regenerators and a plurality of spectral filters, comprising:
bypassing one of the plurality of spectral filters to couple an output terminal of one of the cascaded optical regenerators to a saturable absorber to create an electric field fluctuation that is strong enough to start to generate seed pulses with Q-switched spectra;
injecting the seed pulses to another cascaded optical regenerator to establish a pulsed state in the optical oscillator; and
decoupling the saturable absorber from the output terminal of one of the cascaded optical regenerators and outputting the generated short pulses through the output terminal.

6. The method as in claim 5, wherein the saturable absorber includes a non-polarization-maintaining (non-PM) fiber segment and polarization elements to exhibit a nonlinear polarization evolution (NPE).

7. The device as in claim 5, wherein the saturable absorber has a mode-locking pumping rate that is below a continuous-wave lasing threshold.

8. The device as in claim 5, wherein the saturable absorber includes a semiconductor, a carbon nanotube, a graphene, or a nonlinear loop mirror, or a combination of any two or more of the semiconductor, the carbon nanotube, the graphene, and the nonlinear loop mirror with or without others.

9. An optical device for producing optical pulses, comprising:
an optical oscillator including at least one optical arm including at least one piece of fiber and at least one optical filter;
a starting arm coupled to the at least one optical arm to generate spikes of radiation for the optical oscillator to start pulsation; and
an optical switch coupled between the optical oscillator and the starting arm to connect the starting arm to the at least one optical arm to start the optical oscillator using the spikes of radiation generated by the starting arm.

10. The device as in claim 9, wherein the optical oscillator includes:
a plurality of cascaded optical regenerators including first and second optical regenerators; and
a plurality of spectral filters, each spectral filter being coupled between two consecutively arranged optical regenerators.

11. The device as in claim 10, wherein the starting arm includes a filter bypass path including a saturable absorber couplable to an output of the first optical regenerator by bypassing the spectral filter coupled between the first and second.

12. The device as in claim 11, wherein the optical switch is configured to cause the filter bypass path to be engaged with or disengaged from the first and second optical regenerators.

13. The device as in claim 12, wherein the saturable absorber is configured to generate pulses including powerful-enough spikes of radiation for the main cavity structure to inject seed pulses into the second optical regenerator and start pulsation inside the plurality of cascaded optical regenerators.

14. The device as in claim 11, wherein the first and second spectral filters include a grating spectral filter, an interference filter, a birefringent filter, a fiber Bragg device, or a photonic crystal structure.

15. The device as in claim 11, wherein the saturable absorber includes a non-polarization-maintaining (non-PM) fiber segment and polarization elements to exhibit a nonlinear polarization evolution (NPE).

16. The device as in claim 15, wherein the saturable absorber has a mode-locking pumping rate that is below a continuous-wave lasing threshold.

17. The device as in claim 11, wherein the saturable absorber includes a semiconductor, a carbon nanotube, a graphene, or a nonlinear loop mirror, or a combination of any two or more of the semiconductor, the carbon nanotube, the graphene, and the nonlinear loop mirror with or without others.

18. The device as in claim 11, wherein each of the optical regenerators includes a polarization-maintaining (PM) optical fiber.

19. The device as in claim 11, wherein the optical switch includes a mirror on a flip mount or any kinematic mount.

20. The device as in claim 9, wherein the optical oscillator includes a linear cavity Mamyshev oscillator including one piece of fiber, two filters and two mirrors, one on each end.
